(19) United States
(12) Patent Application Publication
(10) Pub. No.: US 2020/0350167 A1
(43) Pub. Date: Nov. 5, 2020

(54) INORGANIC METALLIC OXIDE THIN FILM WITH COMPOSITE CRYSTAL FORM AND MANUFACTURING METHOD THEREOF

(71) Applicant: SOUTH CHINA UNIVERSITY OF TECHNOLOGY, Guangzhou (CN)

(72) Inventors: Rongsheng CHEN, Guangzhou (CN); Sunbin DENG, Guangzhou (CN); Hoising KWOK, Guangzhou (CN)

(73) Assignee: SOUTH CHINA UNIVERSITY OF TECHNOLOGY, Guangzhou (CN)

(21) Appl. No.: 16/758,678

(22) PCT Filed: Nov. 8, 2017
(86) PCT No.: PCT/CN2017/109812

§ 371 Date: Apr. 23, 2020

(30) Foreign Application Priority Data
Oct. 24, 2017 (CN) 201711000109.5

(51) Int. Cl. H01L 21/02; H01L 29/24; H01L 29/786; C23C 14/08; C23C 14/58

(52) U.S. Cl. CPC H01L 21/02565; H01L 21/02381; H01L 21/02422; H01L 21/02488; C23C 14/5806; H01L 21/02631; H01L 29/247; H01L 29/78693; C23C 14/086; H01L 21/02592

(57) ABSTRACT

Disclosed is an inorganic metal oxide thin film with an embedded crystal morphology, wherein the embedded crystal morphology is composed of crystalline grains and an amorphous matrix, the crystalline grains are embedded in the amorphous matrix, and the grain size ranges from 0.5 nm to 10 nm. Also provided is a manufacturing method of the inorganic metal oxide thin film with the embedded crystal morphology.

### CROSS-REFERENCE TO RELATED APPLICATIONS

This application is the United States National Stage entry under 35 U.S.C. 371 of International Application PCT/CN2017/109812 filed on Nov. 8, 2017, which claims the benefit of Chinese Patent Application No. 201711000109.5, filed on Oct. 24, 2017, the entirety of which is incorporated by reference herein.

### TECHNICAL FIELD

The present disclosure relates to the field of semiconductors, and in particular to an inorganic metal oxide thin film with an embedded crystal morphology and a manufacturing method thereof.

### BACKGROUND

The next generation of active-matrix flat panel display technology is developing towards larger size, higher resolution, higher frame rate, and full integration of peripheral circuits. A thin film transistor (TFT), as a component of a display panel, is required to provide sufficient electrical driving capability. That is, the thin film transistor is demanded to equip with sufficiently high carrier mobility. Inorganic metal oxide thin film transistors have attracted more and more attentions and been intensively studied recently due to their merits such as low cost, low manufacturing temperature, high optical transimittance in the visible band and moderate electrical characteristics. Among them, the most representative examples are bottom-gate type devices with amorphous indium gallium zinc oxide (a-InGaZnO) as their active layers. However, due to the limitations of crystal morphology and element composition of the amorphous indium gallium zinc oxide thin films, the carrier mobility is generally around 10 cm²/Vs, which is relatively low. Therefore, the corresponding TFTs cannot provide sufficient driving capability to completely fulfill application demands from all kinds of display panels. According to the research by K. A. Stewart et al. (SID Symposium Digest of Technical Papers, Vol. 47, pp. 944-946, 2016 and Journal of Non-Crystalline Solids, Vol. 432, pp. 196-199, 2016), there exist theoretically upper limits for carrier mobility in amorphous semiconductors due to the random atomic arrangement. Therefore, to achieve higher carrier mobility, the crystal morphology of inorganic metal oxides should not be limited to be amorphous, and the atomic arrangement therein should be more orderly.

On the other hand, the common low-temperature polycrystalline silicon and metal oxide thin films with larger crystalline grains can indeed present higher carrier mobility than that of their amorphous counterparts, however, the random distribution of grain boundaries therein will deteriorate the electrical uniformity of small-sized devices across large-scale display panels.

Above all, to rationally design thin film microstructure and to successfully realize preparation method thereof are crucial for the further promotion of inorganic metal oxides in the applications of thin-film transistors and even in the field of entire semiconductor devices.

### SUMMARY

In order to improve the aforesaid technical problems, the first objective of the present disclosure is to provide an inorganic metal oxide thin film with an embedded crystal morphology. The thin film should result in high carrier mobility and good device uniformity.

The second objective of the present disclosure is to provide a simple manufacturing method of the inorganic metal oxide thin film with the embedded crystal morphology. The obtained thin film should result in high carrier mobility and good device uniformity.

The first technical solution adopted by the present disclosure is as follows:

An inorganic metal oxide thin film with an embedded crystal morphology, comprising crystalline grains and an amorphous matrix, the crystalline grains being embedded in the amorphous matrix, and having the grain sizes between 0.5 nm and 10 nm.

Further, the composition of the inorganic metal oxide thin film is a metal oxide having at least one element selected from indium, zinc, tin and gallium.

The second technical solution adopted by the present disclosure is as follows:

A manufacturing method of the inorganic metal oxide thin film with an embedded crystal morphology, comprising steps of:

depositing raw material on a substrate by magnetron sputtering or evaporation process to form a layer of an inorganic metal oxide thin film;

wherein the inorganic metal oxide thin film comprises crystalline grains and an amorphous matrix; and

the raw material comprises at least one crystalline inorganic metal oxide.

Further, the crystalline grains are embedded in the amorphous matrix, and have the grain sizes between 0.5 nm and 10 nm.

Further, the composition of the inorganic metal oxide thin film is a metal oxide having at least one element selected from indium, zinc, tin and gallium.

Further, the raw material comprises at least one selected from indium oxide, tin oxide, gallium oxide, zinc oxide, indium tin oxide, indium gallium oxide, indium zinc oxide, tin gallium oxide, tin zinc oxide, gallium zinc oxide, indium tin zinc oxide, indium gallium zinc oxide, indium gallium tin zinc oxide, fluorine-doped tin oxide, fluorine-doped indium tin oxide, fluorine-doped tin gallium oxide, fluorine-doped tin zinc oxide, fluorine-doped indium tin zinc oxide, fluorine-doped indium gallium zinc oxide, and fluorine-doped indium gallium tin zinc oxide.

Further, the method comprises the steps of:

annealing in a mixed gas of oxygen and inert gas, or oxygen or air at a temperature of 100 to 400° C.

Further, the substrate temperature during magnetron sputtering is 23 to 400° C., and the atmosphere of the magnetron sputtering process is a mixed gas of argon and oxygen.

Further, the substrate is fixed on a mechanism that auto-rotates at a constant speed.

Further, the substrate is a silicon substrate, a glass substrate or a flexible material substrate covered with a buffer layer, the buffer layer is a silicon dioxide layer, a silicon nitride layer or a combined layer of silicon oxide and silicon nitride.

The thin film of the present disclosure has the following beneficial effects: The thin film of the present disclosure comprises an embedded crystal morphology, which has both crystalline grains and an amorphous matrix. The crystalline grains therein contribute to more ordered atomic arrangement in the inorganic metal oxide thin film, thereby improving the carrier mobility of the inorganic metal oxide thin film. Meanwhile, the deposited inorganic metal oxide thin film has good spatial uniformity and thus presents excellent and uniform electrical characteristics, since the crystalline grains with a grain size ranging from 0.5 nm to 10 nm are uniformly embedded in the amorphous matrix. Compared with the inorganic metal oxide thin film with the conventionally nanocrystalline morphology, the inorganic metal oxide thin film with the embedded crystal morphology has a lower density of grain boundaries, thereby reducing the defect states caused by the grain boundaries, improving the film quality and electrical characteristics.

The method of the present disclosure has the following beneficial effects. The method comprises the steps of depositing the raw material on the substrate by the magnetron sputtering or evaporation process to form an inorganic metal oxide thin film. The crystalline inorganic metal oxide raw material is deposited on the substrate to form an inorganic metal oxide thin film with crystalline grains embedded in an amorphous matrix. The present method has a simple manufacturing process. Due to the existence of crystalline grains, the atomic arrangement in the inorganic metal oxide thin film manufactured by the present method are more ordered, thereby improving the carrier mobility of the inorganic metal oxide thin film. Meanwhile, due to the co-existence of the crystalline grains and the amorphous matrix, the inorganic metal oxide thin film present good spatial uniformity, and thus has excellent and uniform electrical characteristics. Compared with the inorganic metal oxide thin film with the conventionally nanocrystalline morphology, the inorganic metal oxide thin film with the embedded crystal morphology has a lower density of grain boundaries, thereby reducing the defect states caused by the grain boundaries, improving the film quality and electrical characteristics.

### BRIEF DESCRIPTION OF THE DRAWINGS

FIG. 1 is a cross-sectional schematic diagram of an indium tin zinc oxide thin film with an embedded crystal morphology deposited on a substrate according to Example 2 of the present disclosure;

FIG. 2 is an illustration of depositing the indium tin zinc oxide thin film with the embedded crystal morphology by a magnetron sputtering process according to Example 2 of the present disclosure;

FIG. 3 is an x-ray diffraction spectrum of the indium tin zinc oxide thin film with the embedded crystal morphology according to Example 2 of the present disclosure;

FIG. 4 is a high-resolution transmission electron microscope image of the indium tin zinc oxide thin film with the embedded crystal morphology according to Example 2 of the present disclosure;

FIG. 5 is a graph showing transfer characteristics of a long-channel thin-film transistor manufactured according to Example 3 of the present disclosure; and

FIG. 6 is a graph showing transfer characteristics of a short-channel thin-film transistor manufactured according to Example 3 of the present disclosure.

### DETAILED DESCRIPTION

The present disclosure provides an inorganic metal oxide thin film with an embedded crystal morphology, comprising crystalline grains and an amorphous matrix, wherein the crystalline grains are embedded in the amorphous matrix and the grain size ranges from 0.5 nm to 10 nm.

Further, as a preferred embodiment, the composition of the inorganic metal oxide thin film is a metal oxide composed of at least one element selected from indium, zinc, tin and gallium.

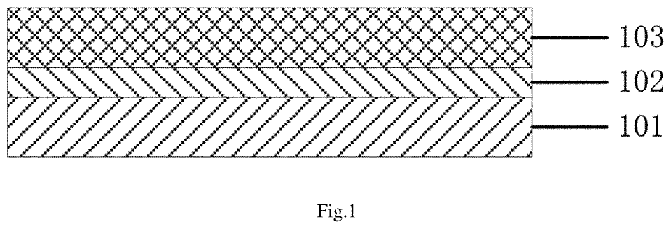

With reference to FIG. 1, a manufacturing method of an inorganic metal oxide thin film with an embedded crystal morphology comprises a step of depositing the raw material on the substrate 101 (the substrate 101 may be a substrate covered with a buffer layer 102) by a magnetron sputtering or evaporation process to form a layer of an inorganic metal oxide thin film;

wherein the inorganic metal oxide thin film comprises crystalline grains and an amorphous matrix;

the raw materials comprise at least one crystalline inorganic metal oxide.

As a further preferred embodiment, the crystalline grains may be embedded in the amorphous matrix, and have the grain size ranging from 0.5 nm to 10 nm.

With reference to FIG. 1, as a further preferred embodiment, the inorganic metal oxide thin film may comprise a metal oxide having at least one element selected from indium, zinc, tin and gallium, for example, indium zinc oxide, tin zinc oxide, indium tin zinc oxide, indium gallium zinc oxide or fluorine-doped tin zinc oxide.

Further, as a preferred embodiment, the raw material may comprise at least one selected from indium oxide, tin oxide, gallium oxide, zinc oxide, indium tin oxide, indium gallium oxide, indium zinc oxide, tin gallium oxide, tin zinc oxide, gallium zinc oxide, indium tin zinc oxide, indium gallium zinc oxide, indium gallium tin zinc oxide, fluorine-doped tin oxide, fluorine-doped indium tin oxide, fluorine-doped tin gallium oxide, fluorine-doped tin zinc oxide, fluorine-doped indium tin zinc oxide, fluorine-doped indium gallium zinc oxide, and fluorine-doped indium gallium tin zinc oxide. For example, a combination of indium zinc oxide, tin zinc oxide, indium tin zinc oxide, indium gallium zinc oxide, fluorine-doped tin zinc oxide, zinc oxide and indium oxide, a combination of tin oxide and zinc oxide, a combination of indium tin oxide and zinc oxide, a combination of indium gallium oxide and zinc oxide, a combination of fluorine-doped tin oxide and zinc oxide, a combination of indium oxide and tin oxide and zinc oxide, and a combination of indium oxide or gallium oxide and zinc oxide.

Further, as a preferred embodiment, the method further may comprise a step of annealing in a mixed gas of oxygen and inert gas, or oxygen or air, at a temperature of 100° C. to 400° C.

Further, as a preferred embodiment, the magnetron sputtering process may be performed at a temperature of 23° C. to 400° C., in a mixed gas composed of argon and oxygen.

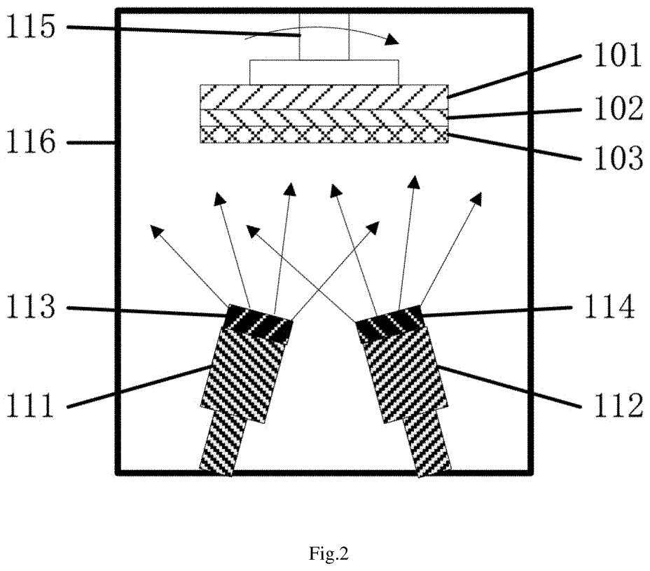

With reference to FIG. 2, as a further preferred embodiment, the substrate 101 may be fixed to a mechanism that auto-rotates at a constant speed. The mechanism may be a clamp, a holder, a chuck, etc., that auto-rotates at a constant speed.

As a further preferred embodiment, the substrate 101 may be a silicon substrate, a glass substrate or a flexible substrate which may be covered with a buffer layer 102, wherein the buffer layer 102 may be a silicon dioxide layer, a silicon nitride layer or a combined layer of silicon oxide and silicon nitride.

Hereinafter, the present disclosure will be further described with reference to the drawings and specific examples.

### EXAMPLE 1

In order to address the issue of carrier mobility suppression as a result of atomic arrangement disorder in amorphous inorganic metal oxide thin films as well as the issue of spatial non-uniformity of electrical characteristics in low-temperature polysilicon thin films and polycrystalline inorganic metal oxide thin films, this example proposes an indium tin zinc oxide thin film with an embedded crystal morphology.

The indium tin zinc oxide thin film with the embedded crystal morphology comprises crystalline grains and an amorphous matrix. The crystalline grains are embedded in the amorphous matrix, so the order degree of the atoms in the indium tin zinc oxide thin film is between its amorphous and polycrystalline counterparts. The grain sizes of the crystal grains are between 0.5 nm and 10 nm. Similarly, the composition of the thin film can be replaced with any one selected from indium tin oxide, indium gallium oxide, indium zinc oxide, tin gallium oxide, tin zinc oxide, gallium zinc oxide, indium tin zinc oxide, indium gallium zinc oxide, indium gallium tin zinc oxide, fluorine-doped tin oxide, fluorine-doped indium tin oxide, fluorine-doped tin gallium oxide, fluorine-doped tin zinc oxide, fluorine-doped indium tin zinc oxide, fluorine-doped indium gallium zinc oxide, and fluorine-doped indium gallium tin zinc oxide.

### EXAMPLE 2

With reference to FIGS. 1 and 2, the manufacturing method of the indium tin zinc oxide thin film with the embedded crystal morphology in this example comprises the following steps:

A1. Depositing a silicon dioxide layer, as a buffer layer 102, on a glass substrate 101 using a plasma enhanced chemical vapor deposition process, as shown in FIG. 1.

A2. Simultaneously magnetron sputtering polycrystalline indium tin oxide target 113 and polycrystalline zinc oxide target 114 on the buffer layer 102 to deposit an indium tin zinc oxide thin film 103 with an embedded crystal morphology, as shown in FIG. 2. The indium tin zinc oxide thin film 103 has a thickness of 50 nm.

A3. Annealing the indium tin zinc oxide thin film with the embedded crystal morphology using a tube furnace at a temperature of 300° C. for 1 hour.

As shown in FIG. 2, the polycrystalline indium tin oxide target 113 had a composition of In₂O₃: SnO₂=9: 1 wt % (weight percentage). The power supply used for sputtering the polycrystalline indium tin oxide target 113 was a direct-current (DC) power supply 111, which loaded a power density of about 5.4 W/cm² on the polycrystalline indium tin oxide target 113. The power supply used for sputtering the polycrystalline zinc oxide target 114 was a radio-frequency (RF) power supply 112, which loaded a power density of about 7.4 W/cm² on the polycrystalline zinc oxide target 114.

When the magnetron sputtering was carried out, the glass substrate 101 on which the silicon dioxide buffer layer 102 was deposited, was fixed to a holder 115 and rotated with the holder 115, to avoid significant thickness variation of the deposited thin film as well as to ensure relatively uniform distribution of the crystalline grains inside the thin film. Therefore, the spatial uniformity of the thin film was improved. Argon and oxygen, which served as reaction gases, were introduced into a sputtering chamber 116 at a flow ratio of 3:2. The working pressure in the sputtering chamber 116 was 3 mTorr, and the magnetron sputtering time was 7 minutes.

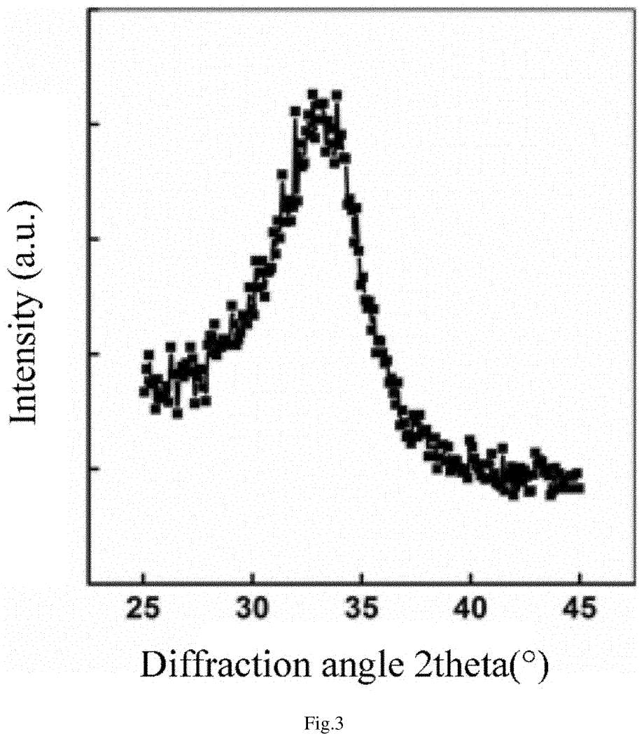

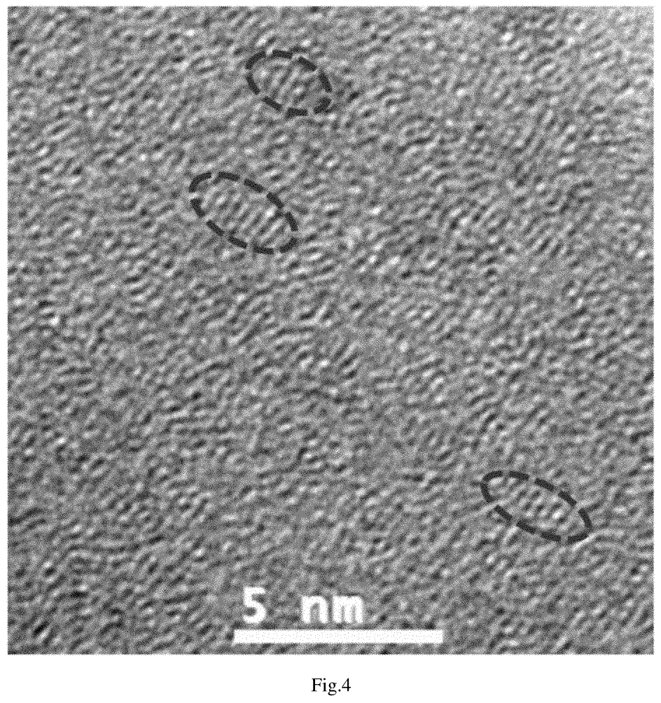

As shown in FIG. 3, the X-ray diffraction spectrum showed a diffraction peak in the vicinity of 33.8°, indicating the existence of crystalline microstructure in the indium tin zinc oxide thin film deposited on the top of the substrate, in the case that the influence of the substrate had been excluded. The high-resolution transmission electron microscope image shown in FIG. 4 further confirms that the indium tin zinc oxide thin film not only has nanocrystalline grains, but also has an amorphous matrix. The nanocrystalline grains are embedded in a framework composed of the amorphous materials. Accordingly, in the present disclosure, the microstructure with the above-mentioned characteristics is referred to as an “embedded crystal morphology”, in which the order degree of atoms should be between the amorphous and polycrystalline counterparts.

The method of this example is simple, reliable and repeatable. Meanwhile, the manufacturing is cost-effective and easy to implement due to fewer steps.

### EXAMPLE 3

The indium tin zinc oxide thin film produced in example 2 was applied to an indium tin zinc oxide thin-film transistor, and the indium tin zinc oxide thin film with the embedded crystal morphology was used as the active layer of the transistor. Then the transfer characteristics of the fabricated transistor were tested.

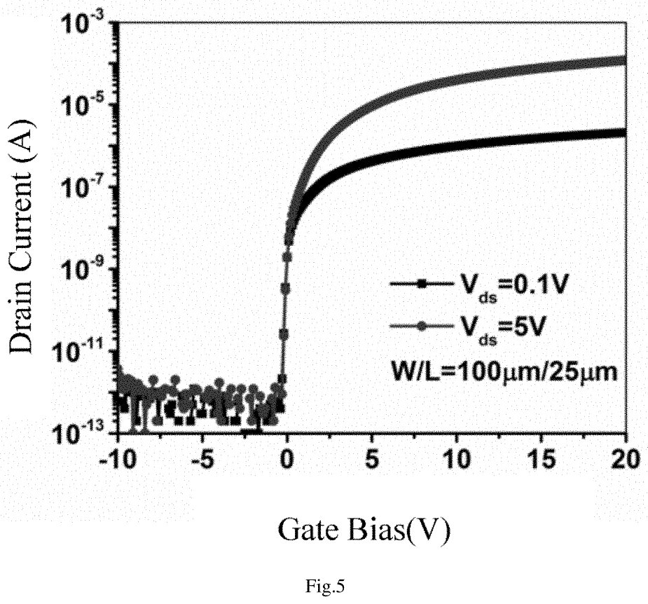

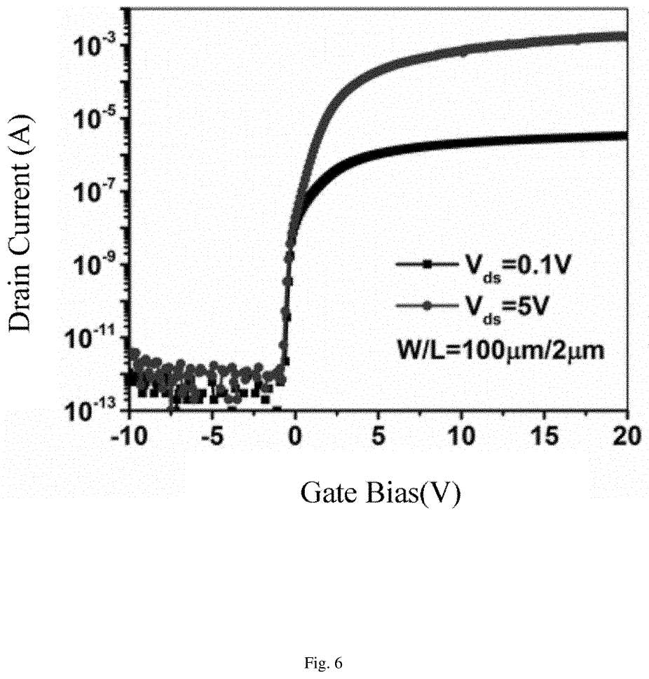

It can be seen from FIGS. 5 and 6 that the transistors (including both long-channel and short-channel thin-film transistors) having the indium tin zinc oxide thin films with the embedded crystal morphology in this example exhibited excellent electrical characteristics, and the short-channel thin-film transistor shows no obvious short-channel effect. It can be extracted from FIGS. 5 and 6 that the transistors having the indium tin zinc oxide thin film with the embedded crystal morphology had a field-effect mobility of over 20 cm²/Vs, and a subthreshold swing of less than 0.15 V/decade. In contrast, the transistor, which had the same structure but with an amorphous indium tin zinc oxide counterpart as the active layer, showed a field-effect mobility of only 10 cm²/Vs. This indicates that the indium tin zinc oxide thin-film transistor with the embedded crystal morphology has higher carrier mobility.

### EXAMPLE 4

Taking a fluorine-doped tin zinc oxide with an embedded crystal morphology as an inorganic metallic oxide thin film with an embedded crystal morphology, this example proposes a manufacturing method of a fluorine-doped tin zinc oxide thin film with an embedded crystal morphology, which includes the following step:

B1. Depositing a layer of silicon dioxide, as a buffer layer, on a glass substrate using a plasma enhanced chemical vapor deposition process.

B2. On the buffer layer, magnetron sputtering the polycrystalline fluorine-doped tin dioxide target (SnO2: SnF2=95:5 wt %) by a DC power supply and simultaneously magnetron sputtering the polycrystalline zinc oxide target by a RF power supply to deposit a fluorine-doped tin zinc oxide thin film with an embedded crystal morphology, resulting in the fluorine-doped tin zinc oxide thin film with a thickness of 50 nm.

B3. Annealing the fluorine-doped tin zinc oxide thin film with an embedded crystal morphology in an atmospheric oven at a temperature of 300° C. for 0.5 hour, then naturally cooling to room temperature.

In this example, when the magnetron sputtering process was carried out, the glass substrate coated with the silicon dioxide buffer layer was fixed to the holder, and rotated with the holder to ensure the uniform thickness of the deposited thin film. Argon and oxygen were introduced into the sputtering chamber both at a flow rate of 10 sccm, and the working pressure was 3 mTorr. The DC power supply loaded a power density of about 4.4 W/cm² on the polycrystalline fluorine-doped tin dioxide target, and the RF power supply loaded a power density of about 7.4 W/cm² on the polycrystalline zinc oxide target. The magnetron sputtering time was 20 minutes.

### EXAMPLE 5

Taking an indium zinc oxide thin film with an embedded crystal morphology as an inorganic metallic oxide thin film with an embedded crystal morphology, this example proposes a manufacturing method of an indium zinc oxide thin film with an embedded crystal morphology, which includes the following step:

C1. Depositing a layer of silicon dioxide, as a buffer layer, on a silicon substrate using a plasma enhanced chemical vapor deposition process.

C2. On the buffer layer, magnetron sputtering the polycrystalline indium oxide target by a DC power supply and simultaneously magnetron sputtering the polycrystalline zinc oxide target by a RF power supply to deposit an indium zinc oxide thin film with an embedded crystal morphology, resulting in an indium zinc oxide thin film with a thickness of 50 nm.

C3. Annealing the indium zinc oxide thin film with an embedded crystal morphology in a tube furnace at a temperature of 300° C. for 0.5 hour, then naturally cooling to room temperature.

In this example, when the magnetron sputtering process was carried out, the silicon substrate coated with the silicon dioxide buffer layer was fixed to the holder, and rotated with the holder to ensure the uniform thickness of the deposited thin film. Argon and oxygen were introduced into the sputtering chamber at a flow rate of 12 sccm and 8 sccm, respectively, and the working pressure was 3 mTorr. The DC power supply loaded a power density about 7.4 W/cm² on the ploycrystalline indium oxide target, and the RF power supply loaded a power density of about 7.4 W/cm² on the polycrystalline zinc oxide target. The magnetron sputtering time was 10 minutes.

The present disclosure has the following advantages.

1) By annealing the inorganic metal oxide thin film with the embedded crystal morphology, defects in the thin film caused by factors such as ion bombardment and the like during the deposition process can be repaired and the quality of the thin film can be improved.

2) The manufacturing method of the present disclosure is simple and easy to implement, which is beneficial to be applied in industry.

3) The inorganic metal oxide material with the embedded crystal morphology manufactured by this method has fewer defect states and higher carrier mobility.

4) The prepared inorganic metal oxide thin film with the embedded crystal morphology has an improved order degree of atoms due to the existence of crystalline grains in the microstructure of the thin film, and thus has higher carrier mobility. In addition, due to the co-existence of the crystalline grains and the amorphous matrix, the thin films of the present disclosure are more spatially uniform than the low-temperature polysilicon thin films and the polycrystalline inorganic metal oxide thin films, so that the corresponding small-sized devices can maintain good and uniform electrical performance in large-scale applications.

The above is detailed description of the preferred embodiments of the present disclosure, but the present disclosure is not limited thereto. Those skilled in the art can make various equivalent variations or substitutions without departing from the principle of the present disclosure. These equivalent variations or substitutions are included in the scope defined by the claims of the present disclosure.

What is claimed is:

1. An inorganic metal oxide thin film with an embedded crystal morphology, comprising an embedded crystal morphology which is composed of crystalline grains and an amorphous matrix, the crystalline grains are embedded in an amorphous matrix, and have grain sizes ranging from 0.5 to 10 nm.

2. The inorganic metal oxide thin film with the embedded crystal morphology according to claim 1, wherein the inorganic metal oxide thin film comprises a metallic oxide having at least one element selected from indium, zinc, tin and gallium.

3. A manufacturing method of an inorganic metal oxide thin film with an embedded crystal morphology, comprising a step of depositing raw material on a substrate by a magnetron sputtering or evaporation process, to form a layer of an inorganic metal oxide thin film,
wherein the inorganic metal oxide thin film comprises crystalline grains and an amorphous matrix; and
wherein the raw material comprises at least one crystalline inorganic metal oxide.

4. The manufacturing method of the inorganic metal oxide thin film with the embedded crystal morphology according to claim 3, wherein the crystalline grains are embedded in an amorphous matrix, and have grain sizes ranging from 0.5 nm to 10 nm.

5. The manufacturing method of the inorganic metal oxide thin film with the embedded crystal morphology according to claim 3, wherein the inorganic metal oxide thin film comprises a metal oxide having at least one element selected from indium, zinc, tin and gallium.

6. The manufacturing method of the inorganic metallic oxide thin film with the embedded crystal morphology according to claim 3, wherein the raw material comprise at least one selected from indium oxide, tin oxide, gallium oxide, zinc oxide, indium tin oxide, indium gallium oxide, indium zinc oxide, tin gallium oxide, tin zinc oxide, gallium zinc oxide, indium tin zinc oxide, indium gallium zinc oxide, indium gallium tin zinc oxide, fluorine-doped tin oxide, fluorine-doped indium tin oxide, fluorine-doped tin gallium oxide, fluorine-doped tin zinc oxide, fluorine-doped indium tin zinc oxide, fluorine-doped indium gallium zinc oxide, and fluorine-doped indium gallium tin zinc oxide.

7. The manufacturing method of the inorganic metal oxide thin film with the embedded crystal morphology according to claim 3, further comprising a step of annealing in a mixed gas of oxygen and an inert gas, or in oxygen or air, at a temperature of 100 ° C. to 400 ° C.

8. The manufacturing method of the inorganic metal oxide thin film with the embedded crystal morphology according to claim 3, wherein the magnetron sputtering process is performed at a temperature of 23 ° C. to 400 ° C., in a mixed gas composed of argon and oxygen.

9. The manufacturing method of the inorganic metal oxide thin film with the embedded crystal morphology according to claim 3, wherein the substrate is fixed to a mechanism that auto-rotates at a constant speed.

10. The manufacturing method of the inorganic metal oxide thin film with the embedded crystal morphology according to claim 3, wherein the substrate is a silicon substrate, a glass substrate or a flexible substrate, which is covered with a buffer layer selected from a silicon dioxide layer, a silicon nitride layer or a combined layer of silicon oxide and silicon nitride.
